(19) United States
(12) Patent Application Publication
(10) Pub. No.: US 2013/0328098 A1
(43) Pub. Date: Dec. 12, 2013

(54) BUFFER LAYER STRUCTURE FOR LIGHT-EMITTING DIODE

(71) Applicant: HIGH POWER OPTO. INC., TAICHUNG CITY (TW)

(72) Inventors: Li-Ping Chou, Taichung City (TW); WEI-YU YEN, Taichung City (TW); Fu-Bang Chen, Taichung City (TW); Chih-Sung Chang, Taichung City (TW)

(73) Assignee: HIGH POWER OPTO. INC., TAICHUNG CITY (TW)

(21) Appl. No.: 13/965,649

(22) Filed: Aug. 13, 2013

Related U.S. Application Data
(63) Continuation-in-part of application No. 13/472,141, filed on May 15, 2012.

(51) Int. Cl. H01L 33/40

(52) U.S. Cl. CPC H01L 33/40
USPC 257/99

(57) ABSTRACT

A buffer layer structure for an LED is provided. The LED includes a P-type electrode, a permanent substrate, a binding layer, a buffer layer, a mirror layer, a P-type semiconductor layer, a light-emitting layer, an N-type semiconductor layer, and an N-type electrode that are stacked in sequence. The buffer layer is a composite material, and includes at least one first material and at least one second material that are alternately stacked. The first material and the second material are mutually diffused to generate gradient variation after the buffer layer is processed by a thermal treatment. Thus, an interface effect and thermal stress between difference interfaces are eliminated, and a channel for ion diffusion is blocked for enhancing light-emitting efficiency of the LED.

This application is a continuation-in-part, and claims priority, of from U.S. patent application Ser. No. 13/472,141 filed on May 15, 2012, entitled “TENSION RELEASE LAYER STRUCTURE OF LIGHT-EMITTING DIODE”, the entire contents of which are hereby incorporated by reference.

### FIELD OF THE INVENTION

The present invention relates to a light-emitting diode (LED), and particularly to an LED for enhancing light-emitting efficiency.

### BACKGROUND OF THE INVENTION

Referring to FIG. 1, a conventional vertical LED includes a sandwich structure formed by an N-type semiconductor layer 1, a light-emitting layer 2 and a P-type semiconductor layer 3. Below the P-type semiconductor layer 3, a mirror layer 4, a buffer layer 5, a binding layer 6, a silicon substrate 7 and a P-type electrode 8 are formed in sequence. A surface of the N-type semiconductor layer 1 is processed by a roughening treatment for increasing light extraction. An

N-type electrode 9 is further provided. By applying a voltage to the N-type electrode 9 and the P-type electrode 8, the N-type semiconductor layer 1 is enabled to provide electrons and the P-type semiconductor layer 3 is enabled to provide holes. Light is produced by the electrons and holes combining at the light-emitting layer 2.

FIG. 2 shows a detailed structure of a conventional buffer layer 5, which is made of alternately stacking two different insulation materials 5A and 5B selected from platinum, nickel, titanium, tungsten, copper, chromium, silicon and aluminum.

A main purpose of the buffer layer 5 formed by the insulation materials 5A and 5B is to release stress between materials and provide an anti-ion diffusion effect. As the Young's modulus of the insulation materials 5A and 5B is between those of the mirror layer 4 and the binding layer 6, the insulation materials 5A and 5B are capable of absorbing stress generated by different materials. Further, as the insulation materials 5A and 5B are physically stable and dense, they are also capable of blocking ion diffusion to prevent the LED from damage. However, the conventional buffer layer 5 is formed by stacking multiple layers of the insulation materials 5A and 5B. Hence, an interface effect is likely to occur between the layers of the insulation materials 5A and 5B, leading to a piezoelectric field effect that generates interface electric charges. As such, light-emitting efficiency is undesirably affected and light-emitting efficiency of the LED is degraded. Further, a mismatch between the insulation materials 5A and 5B being different materials may also arise, such that the stress release effect is reduced. The U.S. Pat. No. 7,211,833, “Light Emitting Diodes Including Barrier Layers/Sublayers”, discloses an LED structure comprising a plurality of alternating layers, a barrier layer and an ohmic layer. The alternating layers include a first layer and a second layer that are alternately stacked. Nonetheless, in addition to a mismatch between the two materials, the alternately-stacked first and second layers substantially involve material interface between them to generate an interface effect. Further, a single layer also has defects to become channels for ion migration. Therefore, the structure of the above disclosure offers unsatisfactory effects in withstanding stress and preventing ion diffusion.

The U.S. Publication No. 2010/0200884, “Light Emitting Device and Light Emitting Device Package”, discloses a buffer layer that is formed by an alloy having a Young's modulus between 9 Gpa and 200 Gpa. Thus, damage or fracture can be prevented when receiving stress, and a material applied to the buffer layer is capable of preventing ion diffusion to other binding layers. However, the alloy is substantially a single-layer material, which offers less satisfactory effects in withstanding stress and preventing ion diffusion compared to an alternately stacked structure.

In the U.S. Publication No. 2009/0297813, “System and Method for Making a Graded Barrier Coating”, FIG. 1 discloses a method for making a graded barrier coating. In the method, a component ratio of a first material to a second material gradually changes with time in an alternating cyclic manner. Therefore, in a deposition layer formed, the component ratio of the first material to the second material displays a gradient change with time in an alternating cyclic manner. Although such prior art eliminates an interface effect generated by a mismatch of material interface, a reduced effect in anti-ion diffusion is at the same time.

### SUMMARY OF THE INVENTION

Therefore the primary object of the present invention is to provide a buffer layer structure for an LED. The buffer layer structure of the present invention is free of an interface effect and effectively blocks ion diffusion to thus enhance light-emitting efficiency of the LED.

A buffer layer structure for an LED is provided according to an embodiment of the present invention. The LED comprises a P-type electrode, a permanent substrate, a binding layer, a buffer layer, a mirror layer, a P-type semiconductor layer, a light-emitting layer, an N-type semiconductor layer and an N-type electrode that are stacked in sequence. The buffer layer of the present invention is a composite material, which includes at least one first material and at least one second material that are alternately stacked. After the buffer layer is processed with a thermal treatment, the first material and the second material are mutually diffused to generate gradient variation. Further, the first material and the second material may be regarded as a group, and the number of the group and the thickness of the group may be appropriately adjusted according to thermal expansion coefficients of the binding layer and the mirror layer. As such, characteristic differences between the binding layer and the mirror layer can be adjusted.

Accordingly, the composite material forming the buffer layer of the present invention is not separated by a distinct interface. That is to say, no interface effect is generated within the composite material of the buffer layer. Thus, interface electric charges are prevented within the buffer layer to eradicate effect of interface electric charges. Further, after the thermal treatment, the first material and the second material are mutually diffused in a way that a channel for ion diffusion is blocked. Hence, the buffer layer of the present invention, when being applied to continual operations, is not only free of ion diffusion, but also buffers a mismatch of films and enhances the stability of the films as the number and thickness of the groups made of the first material and the second material are appropriately provided. Therefore, the present invention offers enhanced light-emitting efficiency of the LED for satisfying usage requirements.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 shows a schematic diagram of a conventional LED.

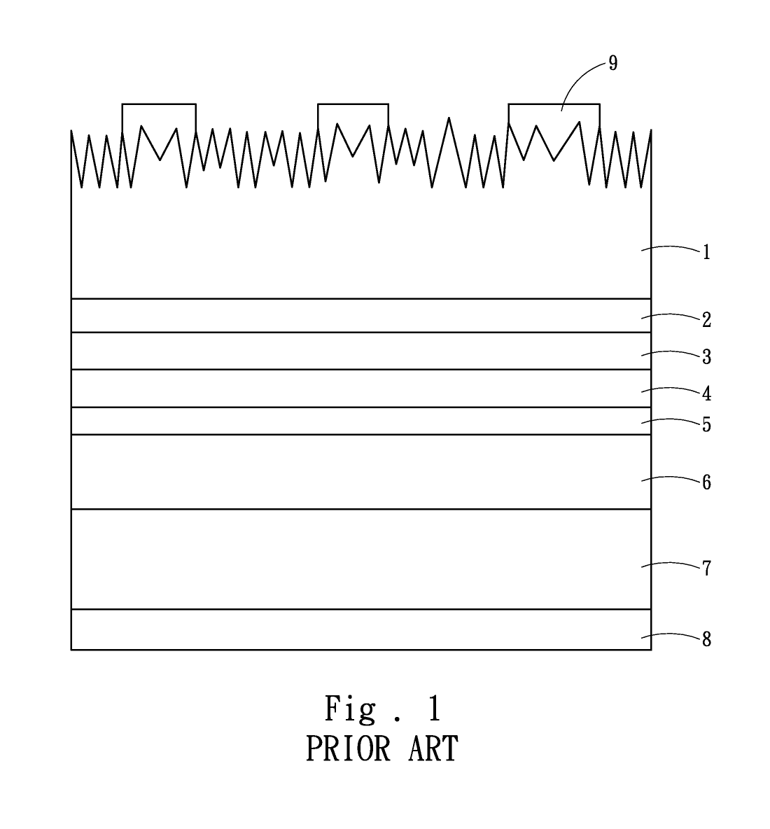

FIG. 2 shows a schematic diagram of a conventional buffer layer.

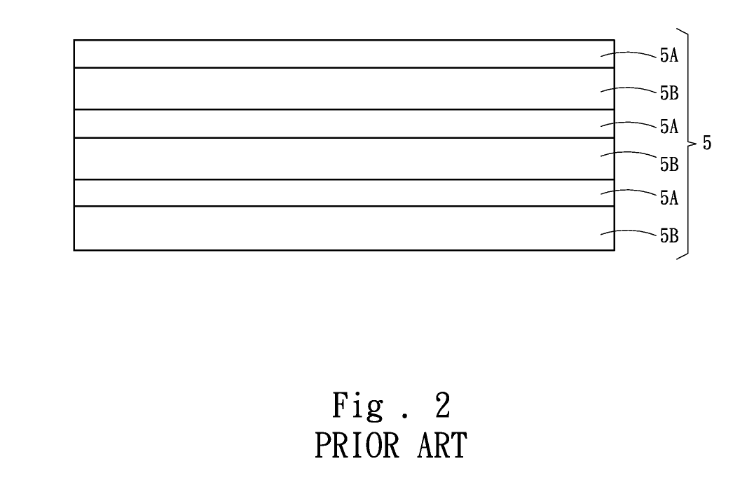

FIG. 3 shows a schematic diagram of an LED according to an embodiment of the present invention.

FIG. 4 shows a first embodiment of the present invention.

FIG. 5 shows a microscope diagram of a buffer layer according to an embodiment of the present invention.

FIG. 6 shows a second embodiment of the present invention.

### DETAILED DESCRIPTION OF THE PREFERRED EMBODIMENTS

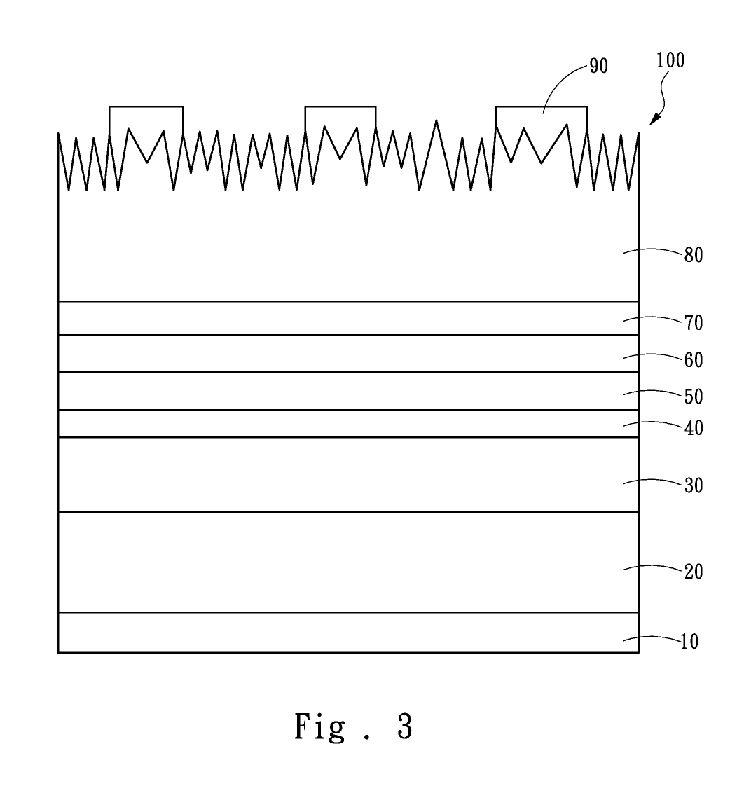

FIG. 3 shows a schematic diagram of a buffer layer structure for a light-emitting diode (LED) according to an embodiment of the present invention. The buffer layer structure is applied to an LED 100. The LED 100 comprises a

P-type electrode 10, a permanent substrate 20, a binding layer 30, a buffer layer 40, a mirror layer 50, a P-type semiconductor layer 60, a light-emitting layer 70, an N-type semiconductor layer 80, and an N-type electrode 90 that are stacked in sequence.

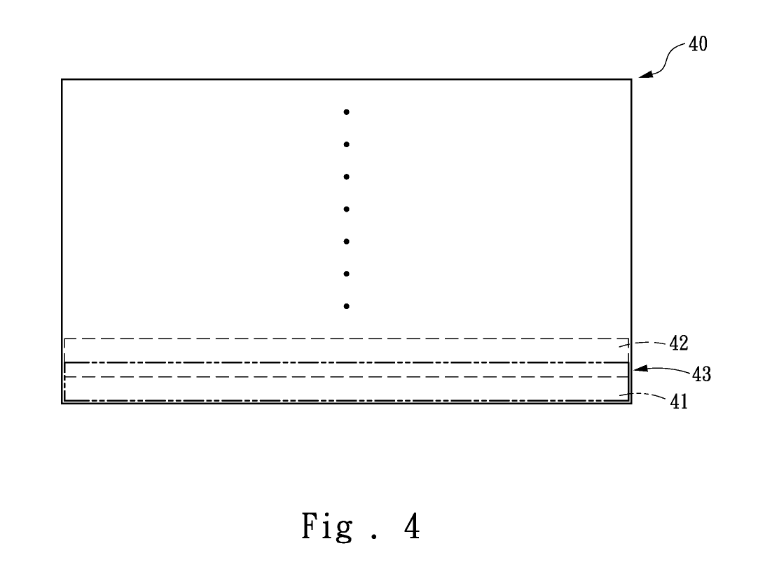

Referring to FIG. 4, the buffer layer 40 of the present invention is a composite material, which includes at least two materials. More specifically, the buffer layer 40 comprises at least one first material 41 and at least one second material 42 that are alternately stacked. One first material 41 and one second material 42 are jointed to become a group 43, and a total thickness of one first material 41 and one second material 42 is regarded as a group thickness (i.e., the thickness of the group 43). Preferably, the group thickness is greater than or equal to 0.001 μm and smaller than or equal to 0.04 μm. After the buffer layer 40 is processed by a thermal treatment, the first material 41 and the second material 42 are mutually diffused to generate gradient variation.

It should be noted that, the first material 41 and the second material 42 are not separated by a distinct interface. In FIG. 4, virtual interface rather than physical interface between the first material 41 and the second material 42 is depicted for illustration purpose. Further, the first material 41 and the second material 42 of the buffer layer 40 are two different materials selected from a group consisting of platinum, rhodium, nickel, titanium, tungsten, chromium, aluminum, tungsten copper, tungsten titanium, tungsten silicide, nitride, and silicon aluminum. Further, after the composite material forming the buffer layer 40 is processed with a thermal treatment, material interface is blended, such that not only an interface effect is prevented for eradicating interface electric charges but also ion diffusion is blocked, thereby maintaining the light-emitting efficiency of the LED and enhancing the stability of the LED.

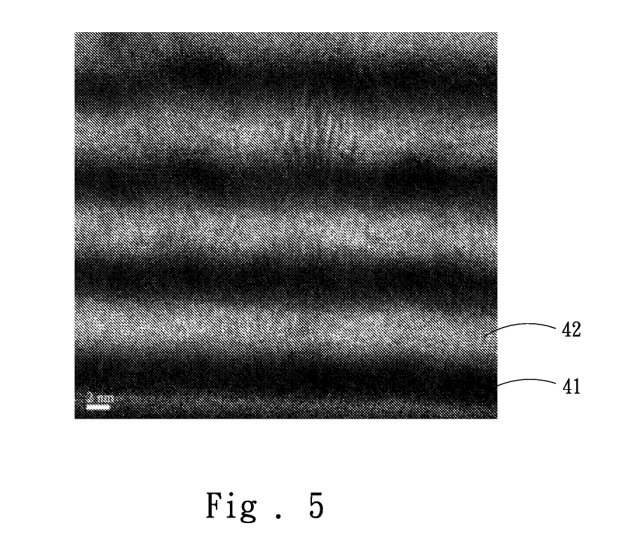

FIG. 5 shows a microscope diagram of a buffer layer according to an embodiment of the present invention. The sum of the thickness of one first material 41 and the thickness of one second material 42 is approximately 0.01 μm. It is seen that, adjacent interfaces of the first material 41 and the second material 42 are mutually diffused to generate gradient variation due to the thermal treatment. Thus, an interface effect and thermal stress between the materials are eliminated while ion diffusion is also blocked.

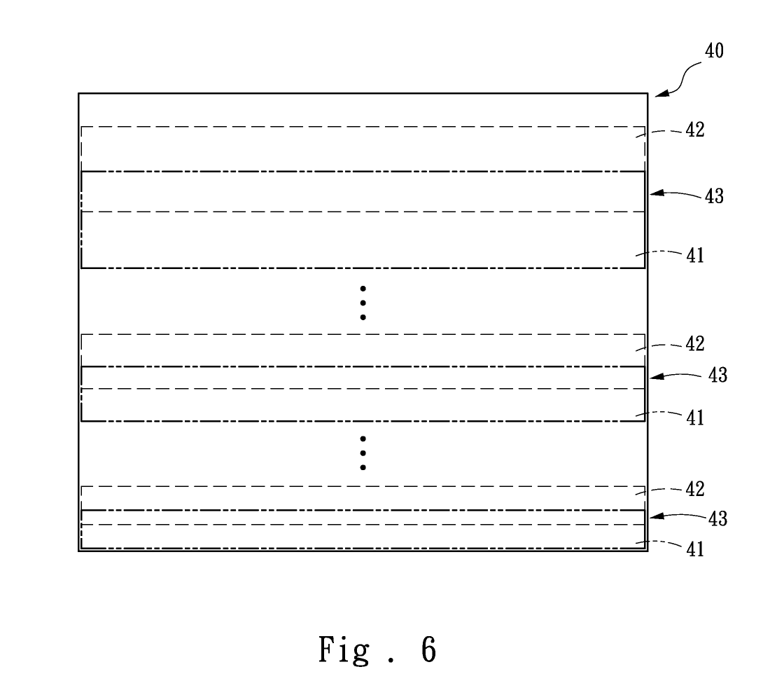

FIG. 6 shows a second embodiment of the present invention. Referring to FIG. 6, the buffer layer 40 may include multiple groups 43 formed by a plurality of first materials 41 and a plurality of second materials 42. The thicknesses of the groups 43 gradually increase by an arithmetic ratio from the mirror layer 50. Further, the maximum thickness of one single group 43 is greater than or equal to 0.001 μm and smaller than or equal to 0.04 μm. Thus, with the thickness of one single group 43 gradually increasing by an arithmetic ratio, the effect of blocking an ion diffusion channel can be enhanced.

In conclusion, the composite material forming the buffer layer of the present invention is not separated by a distinct interface. That is to say, no interface effect is generated within the composite material of the buffer layer. Thus, interface electric charges are prevented within the buffer layer to eradicate effects of interface electric charges and thermal stress. Further, after the thermal treatment, the first material and the second material are mutually diffused in a way that a channel for ion diffusion is blocked, thereby enhancing the light-emitting efficiency of the LED.

What is claimed is:

1. A buffer layer structure for a light-emitting diode (LED), the LED comprising a P-type electrode, a permanent substrate, a binding layer, a buffer layer, a mirror layer, a P-type semiconductor layer, a light-emitting layer, an N-type semiconductor layer, and an N-type electrode that are stacked in sequence, the buffer layer structure being characterized in that:
the buffer layer is a composite material, and comprises at least one first material and at least one second material that are alternately stacked; the first material and the second material are mutually diffused to generate gradient variation after the buffer layer is processed by a thermal treatment.

2. The buffer layer structure of claim 1, wherein a sum of thicknesses of the first material and the second material is greater than or equal to 0.001 μm and smaller than or equal to 0.04 μm.

3. The buffer layer structure of claim 1, wherein the first material and the second material are different materials selected from a group consisting of platinum, rhodium, nickel, titanium, tungsten, chromium, aluminum, tungsten copper, tungsten titanium, tungsten silicide, nitride, and silicon aluminum.

4. The buffer layer structure of claim 1, wherein one first material and one second material form a group, the buffer layer structure of the LED includes a plurality of the groups, and thicknesses of the groups are linearly and arithmetically changed from the mirror layer to the binding layer.

5. The buffer layer structure of claim 4, wherein the thickness of one single group is greater than or equal to 0.001 μm and smaller than or equal to 0.04 μm.
